(19) United States
(12) Patent Application Publication
(10) Pub. No.: US 2021/0024742 A1
(43) Pub. Date: Jan. 28, 2021

(54) CURABLE RESIN COMPOSITION, CURED PRODUCT THEREOF AND PRINTED WIRING BOARD

(71) Applicant: TAIYO INK MFG. CO., LTD., Hiki-gun (JP)

(72) Inventors: Yasuyo KANAZAWA, Hiki-gun (JP); Tomotaka NOGUCHI, Hiki-gun (JP)

(73) Assignee: TAIYO INK MFG. CO., LTD., Hiki-gun (JP)

(21) Appl. No.: 17/043,330

(22) PCT Filed: Mar. 14, 2019
(86) PCT No.: PCT/JP2019/010560

§ 371 Date: Sep. 29, 2020

(30) Foreign Application Priority Data
Mar. 30, 2018 (JP) 2018-069536

(51) Int. Cl. C08L 63/00; H05K 1/02; H05K 9/00

(52) U.S. Cl. CPC C08L 63/00; H05K 1/0216; C08L 2203/20; C08L 2205/025; H05K 9/0083

(57) ABSTRACT

Provided is a curable resin composition which can be suitably used as a hole filling material for a printed wiring board having excellent characteristics such as noise suppression and a high flexibility in wiring formation. A curable resin composition comprising at least a curable resin and a magnetic filler, wherein the viscosity of the curable resin composition is 100 to 3000 (dPa·s) at 5.0 rpm as measured by a cone-flat plate type rotational viscometer (cone-plate type) in accordance with JIS-Z 8803:2011, and a cured product obtained by curing the curable resin composition at 150° C. for 30 minutes has an insulation resistance value of 1.0×10⁵Ω or more.

### BACKGROUND OF THE INVENTION

### Field of the Invention

The present invention relates to a curable resin composition, and more particularly to a curable resin composition which can be suitably used as a filling material for filling a penetrating hole such as a through hole or a recess part in a printed wiring board.

### BACKGROUND ART

Along with the demand for downsizing/high functionalization of electronic devices in recent years, there is also a demand for printed wiring boards to be more multi-layered and to have higher density. For example, there is proposed a wiring board in which a plurality of circuit elements such as a power supply circuit, a high-frequency circuit, and a digital circuit are mounted on one substrate.

Since each circuit element generates noise which affect the adjacent circuit elements in such a substrate having a plurality of circuit elements mounted, it is necessary to mount each circuit element at a fixed interval or to provide a shield between each circuit elements. Therefore, it is difficult to down-size and increase the density of the substrate on which a plurality of circuit elements are mounted.

To solve the above problem, for example, Patent Document 1 proposes even when a plurality of circuit elements are mounted on a multilayered substrate, it is possible to down-size and reduce noise at a low cost by providing a magnetic layer between the substrates in the multilayered wiring substrate or by filling the penetrating via with a magnetic material. In addition, Patent Document 2 proposes filling perforating holes or via holes of a multilayered wiring board with a conductive paste containing a magnetic filler for electrical interlayer connection.

On the other hand, along with the high functionalization of the printed wiring board, improvement in frequency characteristics are made by removing the excessive portion of the plating film on the wall surface of the through hole or the via hole, which is irrelevant to conduction between the layers. For example, Patent Document 3 proposes a printed wiring board provided with a hole part in which a through hole or a via hole is drilled halfway by means of a technique called a back drill method. In addition, Patent Document 4 proposes providing a plating film only on a part of a wall surface of a through hole or a via hole.

### PRIOR ART REFERENCES

### Patent Documents

Patent Document 1: Japanese Patent Application Laid-Open No. 2017-017175

Patent Document 2: Japanese Patent Application Laid-Open No. 2001-203463

Patent Document 3: Japanese Patent Application Laid-Open No. 2007-509487

Patent Document 4: Japanese Patent Application Laid-Open No. 2012-256636

### SUMMARY OF THE INVENTION

### Problem to be Solved by the Invention

In the through-holes and the like of the wiring boards as described in Patent Documents 3 and 4, there is no plating film, etc. formed on a part of the inner wall surface of the hole, or else a part of the plating film is removed and the insulating layer of the wiring board is exposed. When a hole part like the through hole having such a structure is filled with a conductive paste containing a magnetic filler as described in Patent Document 2, there is a possibility that the wiring layers which are not desired to be electrically connected are electrically connected to each other via the conductive paste, and thus the wiring formation in the wiring substrate is sometimes restricted.

Therefore, the object of the present invention is to provide a curable resin composition which can be suitably used as a hole filling material for a printed wiring board having excellent characteristics such as noise suppression and a high flexibility in wiring formation even when a plurality of circuit elements are mounted. Another object of the present invention is to provide a cured product formed using the curable resin composition and a printed wiring board having the cured product.

### Means for Solving the Problem

The present inventors have obtained a finding that by using a magnetic filler and setting the insulation resistance value of a cured product of a curable resin composition to a certain value or more, it is possible to realize a curable resin composition which can be suitably used as a hole filling material for a printed wiring board which is excellent in characteristics such as noise suppression and having a high flexibility in wiring formation. The present invention is based on the above finding.

That is, the curable resin composition of the present invention is a curable resin composition comprising at least a curable resin and a magnetic filler, wherein the viscosity of the curable resin composition is 100 to 3000 (dPa·s) at 5.0 rpm as measured by a cone-flat plate type rotational viscometer (cone-plate type) in accordance with JIS-Z 8803:2011, and a cured product obtained by curing the curable resin composition at 150° C. for 30 minutes has an insulation resistance value of 1.0×10⁵Ω or more.

In the embodiment of the present invention, the content of the magnetic filler is preferably 30 to 70 vol % based on the total amount of the curable resin composition.

In the embodiment of the present invention, the magnetic filler preferably comprises a magnetic material in which the surface of the magnetic particles is covered with an insulating material.

In the embodiment of the present invention, the curable resin composition is preferably used as a filling material for a penetrating hole or a recess part of a printed wiring board.

A cured product according to another embodiment of the present invention is obtained by curing the curable resin composition.

A printed wiring board according to another embodiment of the present invention is characterized by having the cured product.

### Effect of the Invention

According to the present invention, it is possible to provide a curable resin composition which can be suitably used as a hole filling material for a printed wiring board having excellent characteristics such as noise suppression and a high flexibility in wiring formation even when the printed wiring board is mounted with a plurality of circuit elements. According to the present invention, it is also possible to provide a cured product formed by using the curable resin composition and a printed wiring board having the cured product.

### BRIEF DESCRIPTION OF THE DRAWINGS

FIG. 1a is a schematic view explaining a manufacturing step of a printed wiring board having holes to be filled with the curable resin composition of the present invention.

FIG. 1b is a schematic view explaining a manufacturing step of a printed wiring board having holes to be filled with the curable resin composition of the present invention.

FIG. 1c is a schematic view explaining a manufacturing step of a printed wiring board having holes to be filled with the curable resin composition of the present invention.

FIG. 1d is a schematic view explaining a manufacturing step of a printed wiring board having holes to be filled with the curable resin composition of the present invention.

FIG. 2a is a schematic sectional view showing one embodiment of a printed wiring board having holes to be filled with the curable resin composition of the present invention.

FIG. 2b is a schematic sectional view showing one embodiment of a printed wiring board having holes to be filled with the curable resin composition of the present invention.

FIG. 3 is a schematic sectional view showing another embodiment of a printed wiring board having holes to be filled with the curable resin composition of the present invention.

FIG. 4 is a schematic sectional view showing another embodiment of a printed wiring board having holes to be filled with the curable resin composition of the present invention.

FIG. 5 is a schematic sectional view showing another embodiment of a printed wiring board having holes to be filled with the curable resin composition of the present invention.

### DETAILED DESCRIPTION OF THE INVENTION

### <Curable Resin Composition>

The curable resin composition of the present invention comprises at least a curable resin and a magnetic filler. According to the curable resin composition of the present invention, a cured product obtained by curing the curable resin composition at 150° C. for 30 minutes is made to have an insulation resistance value of 1.0×10⁵Ω or more, therefore, even when the cured product was used for a filling material for not only a penetrating hole such as a through hole and a recess part in a single-layered printed wiring board but also a penetrating hole and a recess part in a multilayered printed wiring board as the one described in Patent Documents 3 and 4, it is possible to produce a printed wiring board having a high flexibility in wiring formation since the conductive parts in the substrate can be prevented from electrically connecting to each other, and also possible to improve characteristics such as noise suppression since the filling material comprises a component having magnetic property. Since mismatching occurs with the peripheral member when the insulation resistance value is too high, the upper limit is preferably 3.0×10¹⁹Ω or less. The insulation resistance value of the cured product is the insulation resistance value of the cured product obtained by curing the curable resin composition at 150° C. for 30 minutes using a hot air circulation drying furnace, and for example, as the hot air circulation drying furnace can be used DF610 manufactured by Yamato Scientific Co., Ltd. The insulation resistance value of the cured product refers to a resistance value measured in an environment of room temperature (20 to 25° C.) and 50 to 60% RH using an electrode substrate (FR-4) based on Test Method IPC-B-24 described in IPC-TM-650, by using a device, R8340A ULTRA HIGH RESISTANCE METER manufactured by Advantest Corporation. Hereinafter, each component constituting the curable resin composition of the present invention will be described.

The curable resin composition of the present invention has a viscosity of 100 to 3000 (dPa·s) at 5.0 rpm as measured by a cone-flat plate type rotational viscometer (cone-plate type) according to JIS-Z 8803:2011. The curable resin composition having such a viscosity range can improve workability when used for filling a penetrating hole or a hole part of a recess part in a printed wiring board. A preferred viscosity range of the curable resin composition is 200 to 2500 dPa·s and a more preferred viscosity range is 200 to 2000 dPa·s. Examples of the method for adjusting the viscosity in the above ranges include, but are not limited to, using a liquid resin, reducing the amount of filler, and adding a solvent.

As the curable resin contained in the curable resin composition of the present invention, any curable resin which can be cured by heat or light can be used without particular limitation, and both of thermosetting resins and photo-curable resins may be contained. Among them, a thermosetting resin is preferred.

The curable resin composition of the present invention may also contain an epoxy resin having a bisphenol skeleton. Examples of the epoxy resin having a bisphenol skeleton include bisphenol A type epoxy resin, bisphenol F type epoxy resin, bisphenol E (AD) type epoxy resin, and bisphenol S type epoxy resin, and amongst these, preferred are bisphenol A type epoxy resin, bisphenol F type epoxy resin, and bisphenol E (AD) type epoxy resin. The epoxy resin having a bisphenol skeleton may be used in a liquid, semi-solid, or solid form, and particularly, liquid form is preferred from the viewpoint of filling property. The liquid state is defined as a liquid state having flowability at 20° C.

One of these epoxy resins having a bisphenol type skeleton may be used alone or two or more in combination, and particularly preferably used in combination of the two, bisphenol A type epoxy resin and bisphenol F type epoxy resin. Examples of these commercially available products include jER828, jER834, jER1001 (bisphenol A type epoxy resin), jER807, jER4004P (bisphenol F type epoxy resin), manufactured by Mitsubishi Chemical Corporation, and R710 (bisphenol E type epoxy resin) manufactured by Air Water Co., Ltd.

The thermosetting resin composition of the present invention may also comprise a polyfunctional epoxy resin. Examples of the polyfunctional epoxy resin include a hydroxybenzophenone-type liquid epoxy resin, EP-3300E manufactured by ADEKA CORPORATION and the like; an aminophenol-type liquid epoxy resin (para-amino phenol-type liquid epoxy resin), jER630 manufactured by Mitsubishi Chemical Corporation, ELM-100 manufactured by Sumitomo Chemical Co., Ltd. and the like; a glycidylamine-type epoxy resin, jER604 manufactured by Mitsubishi Chemical Corporation, Epotote YH-434 manufactured by Nippon Steel & Sumikin Chemical Co., Ltd., and Sumi-epoxy ELM-120 manufactured by Sumitomo Chemical Co., Ltd.; a phenol novolac-type epoxy resin, DEN-431 manufactured by Dow Chemical Company, and the like. One of these polyfunctional epoxy resins can be used or two or more of these in a combination.

A carboxyl group-containing resin may be further used as the curable resin when accelerating the thermosetting reaction with the epoxy resin in the curable resin composition of the present invention, or when an alkali-developable curable resin composition is employed as the composition of the present invention. The carboxyl group-containing resin may be a carboxyl group-containing photosensitive resin having an ethylenically unsaturated group, and may or may not have an aromatic ring.

In the curable resin composition of the present invention, a photo-curable resin may be used in place of or in combination with the thermosetting resin described above as the curable resin. Examples of the photo-curable resin include a curable resin which can be cured by a radical addition polymerization reaction by active energy ray. Specific examples of the radical addition-polymerizable component having one or more ethylenically unsaturated groups in a molecule include conventionally known polyester (meth) acrylate, polyether (meth) acrylate, urethane (meth) acrylate, carbonate (meth) acrylate, epoxy (meth) acrylate, and the like. Specifically, at least any one from the following can be appropriately selected and used: diacrylates of glycols such as ethylene glycol, methoxytetraethylene glycol, polyethylene glycol, and propylene glycol; acrylamides such as N,N-dimethylacrylamide, N-methylolacrylamide, and N, N-dimethylaminopropylacrylamide; aminoalkyl acrylates such as N,N-dimethylaminoethyl acrylate and N, N-dimethylaminopropyl acrylate; polyhydric alcohols such as hexanediol, trimethylolpropane, pentaerythritol, dipentaerythritol, tris-hydroxyethyl isocyanurate, and the like, or polyhydric acrylates such as ethylene oxide adducts, propylene oxide adducts, or s-caprolactone adducts thereof; polyhydric acrylates such as phenoxy acrylate, bisphenol A diacrylate, and ethylene oxide adducts or propylene oxide adducts of these phenols; polyhydric acrylates of glycidyl ethers such as glycerin diglycidyl ether, glycerin triglycidyl ether, trimethylolpropane triglycidyl ether, and triglycidyl isocyanurate; acrylates which are obtained by directly acrylating or by urethane-acrylating via diisocyanate, polyols such as polyether polyol, polycarbonate diol, hydroxyl group-terminated polybutadiene, or polyester polyol, despite of the above, and melamine acrylate; and each methacrylate corresponding to the above-described acrylates. Note that, in the present specification, “(meth) acrylate” is a general term for acrylate, methacrylate and mixtures thereof, and the same applies to other similar expressions.

As the photo-curable resin, a photo-polymerizable monomer may be used in addition to the above-mentioned resins and compounds. The photopolymerizable monomer is a monomer having an ethylenically unsaturated double bond. Examples of the photopolymerizable monomer include commonly known polyester (meth) acrylate, polyether (meth) acrylate, urethane (meth) acrylate, carbonate (meth) acrylate, and epoxy (meth) acrylate. Specifically, at least any one from the following can be appropriately selected and used: hydroxyalkyl acrylates such as 2-hydroxyethyl acrylate and 2-hydroxypropyl acrylate; diacrylates of glycols such as ethylene glycol, methoxytetraethylene glycol, polyethylene glycol, and propylene glycol; acrylamides such as N,N-dimethylacrylamide, N-methylol acrylamide, and N,N-dimethylaminopropyl acrylamide; aminoalkyl acrylates such as N,N-dimethylaminoethyl acrylate and N,N-dimethylaminopropyl acrylate; polyhydric alcohols such as hexanediol, trimethylolpropane, pentaerythritol, dipentaerythritol, tris-hydroxyethyl isocyanurate, or ethylene oxide adducts, propylene oxide adducts, or ε-caprolactone adducts thereof; polyhydric acrylates such as phenoxy acrylate, bisphenol A diacrylate, and ethylene oxide adducts or propylene oxide adducts of these phenols; polyhydric acrylates of glycidyl ethers such as glycerin diglycidyl ether, glycerin triglycidyl ether, trimethylolpropane triglycidyl ether, and triglycidyl isocyanurate; acrylates which are obtained by directly acrylating or by urethane-acrylating via diisocyanate, polyols such as polyether polyol, polycarbonate diol, hydroxyl group-terminated polybutadiene, or polyester polyol, despite of the above and melamine acrylate; and each methacrylate corresponding to the above-described acrylates. Such a photopolymerizable monomer can also be used as a reactive diluent.

The photopolymerizable monomer is particularly effective when a carboxyl group-containing non-photosensitive resin having no ethylenically unsaturated double bond is used, since it is necessary to use the photopolymerizable monomer in combination in order to make the composition photo-curable.

The curable resin composition of the present invention is suitably used as a filling material for filling a penetrating hole such as a through hole and a recess part in a printed wiring board, and comprises a filler for stress release due to curing shrinkage of the filling material and for adjusting the linear expansion coefficient. In the present invention, a magnetic filler is used. Since the use of the magnetic filler makes it possible to suppress or absorb noise electromagnetic waves in the adjacent electromagnetic field, it is possible to make a printed wiring board having excellent characteristics such as noise suppression even when the printed wiring board is mounted with a plurality of circuit elements. In the present invention, the magnetic filler means a filler having a magnetic permeability of more than 1.0. The magnetic permeability can be measured at a temperature of 25° C. and a frequency of 10 MHz to 1 GHz using, for example, E5071C ENA network analyzer manufactured by Keysight, as described later, and the measured real part (p′) is determined as the magnetic permeability.

In the present invention, since the insulation resistance value of the cured product obtained by curing the curable resin composition at 150° C. for 30 minutes needs to be 1.0×10⁵ 4 or more, it is preferable to use a non-conductive magnetic filler. Therefore, preferably a magnetic filler having no conductivity can be used. Note that, in the present invention, the magnetic filler having no conductivity means a filler having an electrical resistivity of 1.0×10¹⁵Ω·cm or more. Specific examples include spinel type ferrites such as Mg—Zn ferrite, Mn—Zn ferrite, Mn—Mg ferrite, Cu—Zn ferrite, Mg—Mn—Sr ferrite, and Ni—Zn ferrite, hexagonal type ferrites such as Ba—Zn ferrite, Ba—Mg ferrite, Ba—Ni ferrite, Ba—Co ferrite, and Ba—Ni—Co ferrite, and garnet-type ferrites such as Y ferrite.

Even if the magnetic filler has conductivity, it can be used as the magnetic filler of the present invention by adjusting the compounding amount or by coating the surface of the magnetic filler with an insulating inorganic or organic material. In such case, the surface of the magnetic filler is preferably coated with an insulating inorganic or organic material. Examples of the conductive magnetic filler include pure iron powder, Fe alloys such as Fe—Si-based alloy powder, Fe—Si—Al based alloy powder, Ni powder, Fe—Ni based alloy powder, Fe—Ni—Mo based alloy powder, Fe—Ni—Mo—Cu based alloy powder, Fe—Co based alloy powder, Fe—Ni—Co based alloy powder, Fe—Cr based alloy powder, Fe—Cr—Si based alloy powder, Fe—Ni—Cr based alloy powder, or Fe—Cr—Al based alloy powder, Ni alloys, and amorphous alloys such as Fe-based amorphous and Co-based amorphous.

### [Curable Resin]

A commercially available magnetic filler can be used as the magnetic filler. Specific examples of the commercially available magnetic fillers include “PST-S” manufactured by Sanyo Special Steel Co., Ltd., “AW2-08PF2OF”, “AW2-08PF1OF”, “AW2-08PF3F”, “AW2-08PF-3FG”, “Fe-3.5Si-4.5CrPF2OF”, “Fe-50N iPF2OF”, and “Fe-80Ni-4MoPF2OF” manufactured by Epson Atmix Corporation, and “LD-M”, “LD-MH”, “KNI-106”, “KNI-106GSM”, “KNI-106GS”, “KNI-109”, “KNI-109GSM”, “KNI-109GS”, manufactured by JFE Chemical Corporation, “KNS-415”, “BSF-547”, “BSF-029”, “BSN-125”, “BSN-714”, “BSN-828”, manufactured by TODA KOGYO CORP, and “JR09P2” manufactured by Japan Metals & Chemicals Co., Ltd. One of the magnetic materials may be used alone, or two or more in combination.

The above-mentioned magnetic filler is preferably contained in a proportion of 30 to 70 vol % and more preferably in a proportion of 40 to 70 vol % based on 100 vol % (in terms of solid content) in total of the curable resin composition. When the content of the magnetic filler is within the above range, both the characteristics such as noise suppression and the filling property of the curable resin composition can be attained at a higher level.

The shape of the magnetic filler is not particularly limited, and examples thereof include a spherical shape, a needle shape, a plate shape, a scaly shape, a hollow shape, an undefined shape, a hexagonal shape, a cubic shape, and a flaky shape.

The average particle size of these magnetic fillers is preferably in the range of 0.1 μm to 25 μm and more preferably in the range of 0.1 μm to 15 μm, taking into consideration the dispersibility of the magnetic filler, the filling property in the hole part, and the smoothness when a wiring layer is formed in the portion where the hole is filled. The average particle size means an average primary particle size, and the average particle size (D50) can be measured by a laser diffraction/scattering method.

### [Other Fillers]

The curable resin composition of the present invention may contain other known fillers in addition to the above-mentioned magnetic fillers as long as the properties are not impaired. Specific examples thereof include silica, barium sulfate, calcium carbonate, silicon nitride, aluminum nitride, boron nitride, alumina, titanium oxide, magnesium oxide, aluminum hydroxide, magnesium hydroxide, mica, talc, organic bentonite, and the like. One of these inorganic fillers may be used alone or two or more in combination.

Among these fillers, calcium carbonate, silica, barium sulfate, and aluminum oxide, which are excellent in low hygroscopicity and low volume expansion, are preferably used, and silica and calcium carbonate are more preferably used. Silica may be amorphous or crystalline, or even a mixture thereof. In particular, amorphous (fused) silica is preferred. The calcium carbonate may be either natural heavy calcium carbonate or synthetic precipitated calcium carbonate.

To the curable resin composition of the present invention, fillers treated with fatty acids or amorphous fillers such as organic bentonite and talc may be added to impart thixotropic property.

The curable resin composition of the present invention may contain a silane coupling agent. By blending a silane coupling agent, adhesion between the filler and the curable resin is improved, whereby cracks in the cured product can be suppressed from generating.

### [Curing Agent]

When the curable resin composition of the present invention comprises a thermosetting resin, it is preferable to include a curing agent for curing the thermosetting resin. As for the curing agent, known curing agents can be used that are generally used for curing a thermosetting resin, examples thereof being amines, imidazoles, polyfunctional phenols, acid anhydrides, isocyanates, and polymers containing these functional groups, and plurality of these may be used as necessary. Examples of the amines include dicyandiamide, diaminodiphenylmethane, and the like. Examples of the imidazoles include alkyl-substituted imidazole and benzimidazole. An imidazole compound may be an imidazole latent curing agent such as an imidazole adduct. Examples of polyfunctional phenols include hydroquinone, resorcinol, bisphenol A and halogen compounds thereof, and further, novolac and resol resins which are condensation products of these with aldehyde. Examples of acid anhydrides include phthalic anhydride, hexahydrophthalic anhydride, methyl nasic anhydride, and benzophenone tetracarboxylic acid. Examples of the isocyanates include tolylene diisocyanate, isophorone diisocyanate, and the like, and those obtained by masking the isocyanate with a phenol or the like may be used. One of these curing agents may be used alone or two or more in combination. Among the above curing agents, amines and imidazoles can be preferably used from the viewpoint of adhesion to the conductive part and the insulating part, storage stability, and heat resistance.

The curing agent may be composed mainly of an adduct compound of an aliphatic polyamine such as alkylenediamine having 2 to 6 carbons, polyalkylenepolyamine having 2 to 6 carbons, or aromatic ring-containing aliphatic polyamine having 8 to 15 carbons, or an adduct compound of an alicyclic polyamine such as isophorone diamine or 1,3-bis (aminomethyl) cyclohexane, or a mixture of the above-described aliphatic polyamine adduct compound and the above-described alicyclic polyamine adduct compound.

The adduct compound of the aliphatic polyamine as above is preferably obtained by addition reaction of the aliphatic polyamine with aryl glycidyl ether (particularly phenyl glycidyl ether or tolyl glycidyl ether) or a compound obtained by addition reaction of alkyl glycidyl ether. The adduct compound of the alicyclic polyamine as above is preferably obtained by addition reaction of said alicyclic polyamine with n-butyl glycidyl ether, bisphenol A diglycidyl ether, and the like.

Examples of the aliphatic polyamine include alkylenediamines having 2 to 6 carbons, such as ethylenediamine and propylenediamine; polyalkylenepolyamines having 2 to 6 carbons, such as diethylenetriamine and triethylenetriamine; and aromatic ring-containing aliphatic polyamines having 8 to 15 carbons such as xylylenediamine. Examples of commercially available modified aliphatic polyamines include Fujicure FXE-1000 or Fujicure FXR-1020, Fujicure FXR-1030, Fujicure FXR-1080, Fujicure FXR-1090M2 (manufactured by Fuji Kasei Industries, Ltd), ANCAMINE 2089K, SUNMIDE P-117, SUNMIDE X-4150, ANCAMINE 2422, Surwet R, SUNMIDE TX-3000, and SUNMIDE A-100 (manufactured by Air Products Japan K.K.).

Examples of the cycloaliphatic polyamine include isophorone diamine, 1,3-bis (aminomethyl) cyclohexane, bis(4-aminocyclohexyl)methane, norbornendiam ine, 1,2-diaminocyclohexane, laromin, and the like. Examples of commercially available modified cycloaliphatic polyamines include ANCAMINE 1618, ANCAMINE 2074, ANCAMINE 2596, ANCAMINE 2199, SUNMIDE IM-544, SUNMIDE 1-544, ANCAMINE 2075, ANCAMINE 2280, ANCAMINE 1934, ANCAMINE 2228 (manufactured by Air Products Japan K.K.), DAITOCURAR F-5197, DAITOCURAR B-1616 (manufactured by Daito Sangyo Co., Ltd.), FUJICURE FXD-821, FUJICURE 4233 (manufactured by Fuji Kasei Industry Co., Ltd.), jERcure 113 (manufactured by Mitsubishi Chemical Corporation), and laromin C-260(manufactured by BASF Japan Co., Ltd.). Other examples of the polyamine-type curing agent include EH-5015S (manufactured by ADEKA CORPORATION).

The imidazole latent curing agent is, for example, a reaction product of an epoxy resin and imidazole. Examples include 2-methyl imidazole, 4-methyl-2-ethyl imidazole, 2-phenyl imidazole, 4-methyl-2-phenyl imidazole, 1-benzyl-2-methyl imidazole, 2-ethyl imidazole, 2-isopropyl imidazole, 1-cyanoethyl-2-methyl imidazole, 1-cyanoethyl-2-ethyl-4-methyl imidazole, 1-cyanoethyl-2-undecyl imidazole, and the like. Examples of commercially available products of the imidazole compound include imidazoles such as 2E4MZ, C11Z, C17Z, and 2PZ; AZINE (azine) compounds of imidazoles such as 2MZ-A, 2MZA-PW, and 2E4MZ-A; isocyanurate salts of imidazoles such as 2MZ-OK and 2PZ-OK, and imidazole hydroxymethyl compounds such as 2PHZ and 2P4MHZ (all of which are manufactured by SHIKOKU CHEMICALS CORPORATION). Examples of commercial products of the imidazole-type latent curing agent include Curezol P-0505 (manufactured by SHIKOKU CHEMICALS CORPORATION).

From the viewpoint of storage stability, when a thermosetting resin is contained, the amount of the curing agent to be compounded is preferably 1 to 35 parts by mass and more preferably 4 to 30 parts by mass, based on 100 parts by mass of the thermosetting resin, in terms of solid content.

The curable resin composition of the present invention may further contain, if necessary, an oxazine compound having an oxazine ring obtainable from reaction of a phenolic compound, formalin, and primary amine. By containing the oxazine compound, the cured product can be easily roughened by an aqueous solution of potassium permanganate or the like when the curable resin composition filled in the holes of the printed wiring board is cured and subsequently non-electrolytic plated on the cured product, and thus the peel strength with plating can be improved.

Further, a known coloring agent such as phthalocyanine blue, phthalocyanine green, disazo yellow, carbon black, naphthalene black, which is used in an ordinary resist ink for screen printing, may be added.

Further, in order to impart storage stability during storage, known thermal polymerization inhibitors such as hydroquinone, hydroquinone monomethyl ether, tert-butyl catechol, pyrogallol, phenothiazine, and the like, known thickeners such as clay, kaolin, organic bentonite, montmorillonite, and the like for adjusting viscosity, and thixotropic agents can be added. In addition, known additives such as antifoaming agents of silicone type, fluorine type, and polymer type, leveling agents, and adhesion imparting agents of imidazole type, thiazole type, and triazole type, and silane coupling agents can be formulated. In particular, in the case where organic bentonite is used, a portion protruding from the surface of the hole is formed in a protruding state that is easy to polish and remove, resulting in excellent polishing property, which is preferable.

The curable resin composition of the present invention does not necessarily require the use of a diluting solvent; however a small amount of a diluting solvent may be added to adjust the viscosity of the composition. Examples of the diluting solvent include ketones such as methyl ethyl ketone and cyclohexanone; aromatic hydrocarbons such as toluene, xylene, and tetramethylbenzene; glycol ethers such as methyl cellosolve, butyl cellosolve, methyl carbitol, ethyl carbitol, butyl carbitol, propylene glycol monomethyl ether, dipropylene glycol monoethyl ether, and triethylene glycol monoethyl ether; esters such as ethyl acetate, butyl acetate, and acetate esters of the above-described glycol ethers; alcohols such as ethanol, propanol, ethylene glycol, and propylene glycol; aliphatic hydrocarbons such as octane and decane; and organic solvents such as petroleum solvents such as petroleum ether, petroleum naphtha, hydrogenated petroleum naphtha, and solvent naphtha. These may be used alone or two or more of these in combination.

In particular, the curable resin composition as above is suitably used for forming a cured film in a printed wiring board, and can be used as a solder resist, an interlayer insulating material, a marking ink, a coverlay, a solder dam, a filling material for filling a penetrating hole of a through hole, a via hole, and a hole part of a recess part of a printed wiring board. Among them, from the viewpoint of achieving both the magnetic property and the hole-filling property, the composition can be suitably used as a filling material for filling a penetrating hole of a through hole, a via hole, and a hole part of a recess part of a printed wiring board. The curable resin composition according to the present invention may be one-part liquid or two-part or more.

In particular, when the curable resin composition of the present invention is used as a filling material for filling a penetrating hole of a through hole, a via hole, and a hole part of a recess part of a printed wiring board, excellent characteristics such as noise suppression and high flexibility of wiring formation can be obtained for the printed wiring board. Therefore, the composition can be used not only in a single-layered printed wiring board, but also especially suitably in a multilayered printed wiring board on which a plurality of circuit elements are mounted. Embodiment of the printed wiring board including a multilayered printed wiring board in the case where the curable resin composition of the present invention is used as a filling material for filling a penetrating hole or a hole part of a recess part will be described with reference to the drawings.

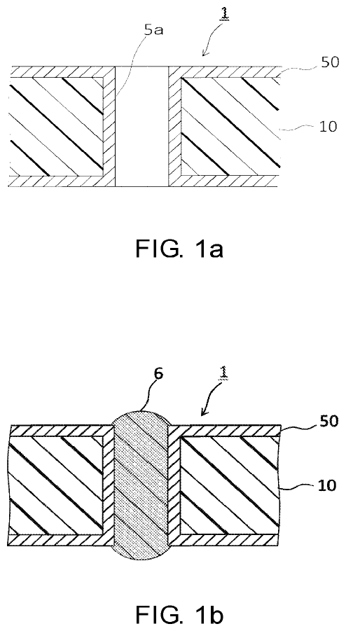

First, a method for filling holes such as a hole part by applying the curable resin composition of the present invention to a general printed wiring board will be described with reference to the drawings. FIGS. 1a to 1d are schematic diagrams illustrating a step of filling a penetrating hole (through hole) of a printed wiring board with the curable resin composition. First, a printed wiring board 1 having a penetrating hole 5a in which the inner wall surface is plated is prepared (FIG. 1a). Preferred use as the printed wiring board 1 as shown in FIG. 1a is one in which a penetrating hole is formed by a drill or the like on the surface of an insulating layer 10 provided with a wiring layer 50 on its surface, and the inner wall of the penetrating hole 5a and the surface of the wiring layer is treated with non-electrolytic plating or electrolytic plating.

Next, the penetrating hole 5a is filled with a curable resin composition. Examples of the filling method include a method in which a mask having an opening in the through penetrating portion is placed on a printed board, and the curable resin composition is applied through the mask by a printing method and the like, and a method in which the penetrating hole is filled with the curable resin composition by a dot printing method and the like. Thereafter, the printed wiring board 1 is heated so that the filled curable resin composition is pre-cured (FIG. 1b). Pre-curing generally refers to a state in which the reaction rate of the epoxy resin is 80% to 97%. Pre-curing is preferably performed by conducting primary pre-curing of the curable resin composition at a relatively low temperature, and then secondary pre-curing of the curable resin composition at a higher temperature than that of the primary pre-curing. By performing pre-curing in this manner, the unnecessary portion of pre-cured product 6 protruding from the surface of the printed wiring board 1, as described later, can be easily removed by physical polishing, and a flat surface can be obtained. The hardness of the pre-cured product 6 can be adjusted by changing the heating time and the heating temperature in pre-curing.

Subsequently, the unnecessary portion of the pre-cured product 6 protruding from the surface of the penetrating hole 5a is removed by polishing to be planarized (FIG. 1c). Polishing can be suitably performed by belt sander, buffing, or the like.

Next, the surface of the printed wiring board 1 is pretreated by buffing or roughening as necessary, and then outer insulating layer 7 is formed (FIG. 1d). By this pretreatment, the surface of the wiring layer 50 is formed into a roughened surface having an excellent anchor effect, and as a result, adhesion with the outer insulating layer 7 becomes excellent. The outer insulating layer 7 is a solder resist layer (not illustrated), an insulating resin layer (not illustrated), a protective mask (not illustrated), or the like, depending on the subsequent treatment, and can be formed by applying a curable resin composition such as various known thermosetting resin compositions, and photo-curable and thermosetting resin compositions, or by laminating a dry film or a prepreg sheet. In the case of forming a fine pattern on the outer insulating layer 7, it is preferable to use a photocurable or thermosetting resin composition or a dry film thereof.

Subsequently, the printed wiring board 1 is heated to be fully cured (finish cured) to form the outer insulating layer 7. In the case where a photo-curable or thermosetting resin composition is used for forming the outer insulating layer 7, it is dried (temporarily cured), exposed according to a known method, and then finally cured. When a double-sided substrate as shown in FIG. 1 (a) is used as the printed wiring board 1, a multilayered printed wiring board can also be formed by alternately repeating the formation of the wiring layer 50 and the formation of the insulating layer 10, and forming the penetrating hole 5a by a well-known method.

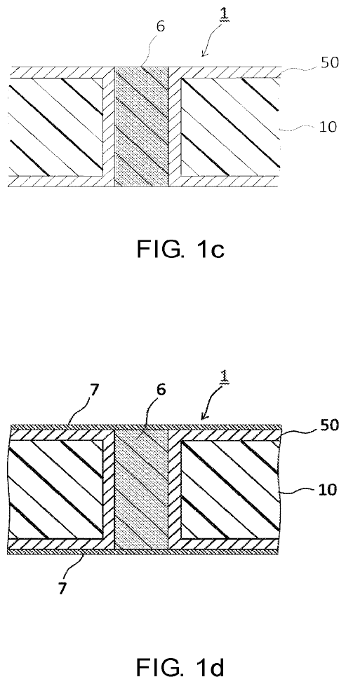

FIGS. 2a to 2b are schematic sectional views showing one example of a part of the manufacturing process of the printed wiring board of the present invention. First, a printed wiring board 2 in which copper foil 8 is laminated on both sides of a substrate 9 is prepared. The surface of the substrate 9 may be subjected to non-electrolytic plating and electrolytic plating for thickening, and a plating film (not illustrated) may be formed on the surface of the substrate 9. The non-electrolytic plating and the electrolytic plating are preferably copper plating. Thereafter, a penetrating hole 5b is formed by drilling with a drill or the like as shown in FIG. 2a. As the substrate 9, a glass epoxy substrate, a polyimide substrate, a bismaleimide-triazine resin substrate, a resin substrate such as a fluororesin substrate, or a copper-clad laminate of these resin substrates, a ceramic substrate, a metal substrate, and the like can be used.

Into the penetrating hole 5b formed in the printed wiring board 2 is filled with the curable resin composition of the present invention. More specifically, a mask (not illustrated) having an opening corresponding to the hole diameter of the penetrating hole 5b can be placed on the printed wiring board 2 so that the penetrating hole 5b can be easily filled by coating using a printing method or a dot printing method. Next, after the curable resin composition is cured by heating and the like to form a pre-cured product 6, the unnecessary portion of the pre-cured product 6 protruding from the through hole 5b is removed by polishing to be planarized in the same manner as described above (FIG. 2b). The polishing can be performed by belt sander, buffing, or the like.

A plating film (not illustrated) may be further formed on the surface of the printed wiring board 2 in which the penetrating hole 5b is filled. Thereafter, an etching resist is formed, and a portion where no resist is formed is etched. Next, the etching resist may be removed to form a conductor circuit layer (not illustrated).

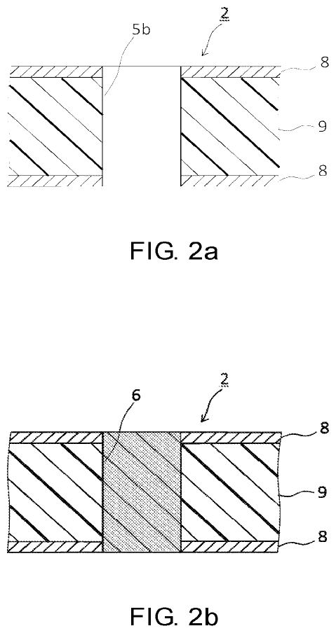

FIG. 3 is a schematic sectional view showing one embodiment of a multilayered printed wiring board in which the holes are filled with a curable resin composition. A multilayered printed wiring board (3) to which a curable resin composition is applied has a plurality of wiring layers (20a, 20b, 20c, 20d) composed of a plating film or the like laminated in the thickness direction thereof via an insulating layer (10) and has a penetrating hole (40) (a hole part to be filled with the curable resin composition) formed in the thickness direction of the plurality of wiring layers (20a, 20b, 20c, 20d). At one end of the hole part of the penetrating hole 40, a conductive part 20e extending from the wiring layer 20d is formed on the inner wall of the penetrating hole 40. At the other end of the hole part of the penetrating hole 40, the inner diameter of the penetrating hole is enlarged so that a part of the wiring layer 20a is removed after the conductive part 20e is formed, and the insulating layer is exposed on the inner wall of the hole part so a state is obtained where the insulating part 10a is formed. That is, the inner wall of the penetrating hole 40 (hole part) is provided with the conductive part 20e and the insulating part 10a. By providing the conductive part 20e and the insulating part 10a on the inner wall of the penetrating hole 40 (hole part) as such, a portion is formed which is not electrically connected, and as a result, improvement is made in the transmission efficiency. The penetrating hole 40 (hole part) having such a cross-sectional shape is filled with a curable resin composition, and the hole is filled by heat curing. Note that, in this embodiment, the insulating layer refers to a layer that supports the wiring layer while insulating the different wiring layers, and the wiring layer refers to a layer that conducts electricity through a circuit. The insulating part refers to a part where each layer is not electrically conductive, and may include the insulating layer described above. On the other hand, the conductive part refers to a part for electrically conducting the plating film and each wiring layer, and may also include the aforementioned wiring layer. Further, the penetrating hole is a hole provided so as to penetrate through the entire thickness direction of the multilayer printed wiring board. The penetrating hole may be formed in the thickness direction of the wiring layer, and more specifically, may not be formed in parallel with the wiring layer. Note that, in the present embodiment, the wiring layer extending to the wall surface of the penetrating hole is used as the conductive part; however, the conductive part can also be applicable in the case where a part of the wiring layer is exposed to the wall surface of the penetrating hole. In addition, the case where a conductive film is formed on the wall surface by plating or the like is also referred to as a conductive part as well as the case where the wiring layer is formed by extending to the wall surface. Since the cured product filled in the penetrating hole 40 of the multilayered printed wiring board having the above-described structure has an insulating property, there is no case where the wiring layers 20a and 20d are electrically connected.

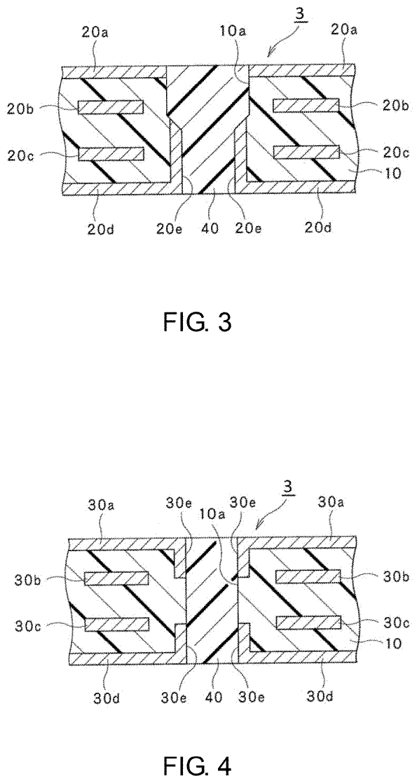

In another embodiment of the present invention, the hole part of the penetrating hole may have a shape as shown in FIG. 4 for example, in addition to the above shape. That is, a multilayered printed wiring board may have the structure in which the wiring layers 30a and 30d extend to the inner wall of the penetrating hole 40 (hole part) to form a conductive part 30e, and a part of the conductive part is removed to expose the insulating layer, whereby the conductive part 30e and the insulating part 10a are provided in the penetrating hole of the multilayered printed wiring board. Note that, in the present embodiment, the wiring layer extending to the wall surface of the penetrating hole is used as the conductive part; however in the case where a part of the wiring layer is exposed to the wall surface of the penetrating hole is also referred to as a conductive part. In addition to the case where the wiring layer is formed by extending to the wall surface, the case where the conductive film is formed on the wall surface by plating or the like is also referred to as a conductive part. Since the cured product filled in the penetrating hole 40 of the multilayered printed wiring board having the above-described structure has an insulating property, there is no case where the wiring layers 30a and 30d are electrically connected.

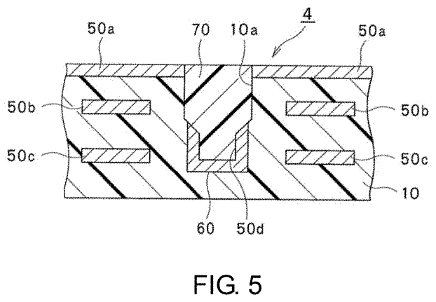

In another embodiment of the present invention, the curable resin composition may be used for, not limited to filling of the penetrating holes, but also a multilayered printed wiring board 4 having a recess part 70 as shown in FIG. 5, for example. The multilayered printed wiring board 4 is in a state where a wiring layer 50a provided on one surface of an insulating layer 10 extends to a wall surface and a bottom part 60 of a recess part 70 to form a conductive part 50d, the opening side of the recess part 70 has an enlarged inner diameter of the recess part so that a part of the wiring layer 50a is removed after the conductive part 50d is formed, and an insulating part 10a is formed by exposing the insulating layer on the inner wall of the hole part. That is, the inner wall of the recess part (hole part) having the bottom part is provided with the conductive part 50d and the insulating part 10a. Note that, in the present embodiment, the wiring layer extending to the wall surface of the recess part is used as the conductive part; however, in the case where a part of the wiring layer is exposed to the wall surface of the recess part can also be referred to as the conductive part. In such a multilayered printed wiring board 4, when the recess part 70 having the bottom portion 60 is filled with the curable resin composition, the curable resin composition comes into contact with both the conductive part extending from the wiring layer 50a and the insulating part exposed on the wall surface of the recess part 70. In addition, the case where the wiring layer is formed by extending to the wall surface as mentioned and also the case where the conductive film is formed on the wall surface by plating or the like can also be referred to as the conductive part. In the present embodiment, the recess part refers to the part of the surface of the multilayered printed wiring board, which is identified to be recessed more clearly than the other parts. Since the cured product filled in the penetrating hole 40 of the multilayered printed wiring board having the above-described structure has an insulating property, there is no case where the wiring layers 50a and 50d are electrically connected.

In the multilayered printed wiring board, as for the ranges of the inner diameter and the depth of the penetrating hole or a recess part having the bottom part, the inner diameter is preferably 0.1 to 1 mm and the depth is 0.1 to 10 mm, respectively.

Although the wiring layer forming the conductive part is, without particular limitation, copper plating, gold plating, tin plating, and the like; and in view of the filling property of the curable resin composition and the adhesion property with the cured product to be described later, plating is preferably of copper. Similarly, examples of the insulating layer constituting the printed wiring board include paper phenol, paper epoxy, glass cloth epoxy, glass polyimide, glass cloth/nonwoven epoxy, glass cloth/paper epoxy, synthetic fiber epoxy, fluorine-based resin, polyphenylene ether, polyphenylene oxide, cyanate ester, polyimide, PET, glass, ceramic, silicon wafer, and the like. Amongst these, in view of the filling property of the curable resin composition and the adhesion property with the cured product, it is preferable that the layer is made of glass cloth/nonwoven fabric epoxy, polyphenylene ether, polyimide, and ceramic, and more preferably, an epoxy-resin-containing cured product. The epoxy resin-containing cured product refers to a cured product of an epoxy resin which is impregnated with glass fibers or a cured product of a resin composition comprising an epoxy resin.

In the case where the curable resin composition is used as a filling material, the filling material is filled into a hole part of a penetrating hole or a recess part having a bottom part of the multilayered printed wiring board of the above-described embodiment, for example, by using a known patterning method such as a screen printing method, a roll coating method, a die coating method, and a vacuum printing method. At this time, the composition is completely filled so as to protrude a little from the hole part or the recess part. A multilayered printed wiring board in which the hole part and the recess part are filled with the curable resin composition is heated at, for example, 80 to 160° C. for about 30 to 180 minutes, and as a result, the curable resin composition is cured and a cured product is formed. The curing of the curable resin composition may be carried out in 2 steps from the viewpoint of easily removing the unnecessary portion protruding from the substrate surface after filling the holes by physical polishing. That is, the curable resin composition can be pre-cured at a lower temperature, and then subjected to final curing (finish curing). The conditions for the pre-curing are preferably heating at 80 to 130° C. for about 30 to 180 minutes. Since the hardness of the pre-cured product is relatively low, the unnecessary portion protruding from the surface of the substrate can be easily removed by physical polishing, and a flat surface can be obtained. Then, heating is performed for final curing. The conditions for final curing are preferably heating at 130 to 160° C. for about 30 to 180 minutes. In both of the pre-curing and the final curing, curing can be carried out using a hot air circulation drying furnace, an IR furnace, a hot plate, a convection oven, and the like (a method of bringing hot air in a dryer into counter-flow contact using a heat source of an air heating system using steam and a method of blowing the hot air against a material to be cured through a nozzle). Amongst these, a hot air circulation drying furnace is particularly preferable. At this time, the cured product hardly expands or contracts due to the low expansion property, and becomes a final cured product having good dimensional stability and excellent low hygroscopicity, adhesion property, electrical insulation property, and the like. Note that, the hardness of the pre-cured product can be controlled by changing the heating time and heating temperature for pre-curing.

After the curable resin composition is cured as described above, the unnecessary portion of the cured product protruding from the surface of the printed wiring board is removed by a known physical polishing method, and after planarization, the wiring layer on the surface is patterned into a predetermined pattern to form a predetermined circuit pattern. If necessary, the surface of the cured product may be roughened with an aqueous solution of potassium permanganate or the like, and then a wiring layer may be formed on the cured product by non-electrolytic plating or the like.

### EXAMPLES

The present invention will be described in further detail with reference to the following examples; however, the present invention is not limited to these examples. In the following, “part” and “%” are all on a mass basis unless otherwise specified.

### <Preparation of Curable Resin Composition>

Various components shown in Table 1 below were mixed in the proportions (parts by mass) shown in the respective tables, and pre-mixed with an agitator to prepare the respective curable resin compositions of Examples 1 to 3 and Comparative Examples 1 to 4. Note that, the amount of each filler in the table was adjusted to be constant at 50 vol %.

Note that, *1 to *10 in Table 1 represent the following components.
*1: jER828 (bisphenol A type liquid epoxy resin) manufactured by Mitsubishi Chemical Corporation
*2: jER807 (bisphenol F type liquid epoxy resin) manufactured by

Mitsubishi Chemical Corporation
*3: jER1001 (bisphenol A type liquid epoxy resin) manufactured by Mitsubishi Chemical Corporation
*4: E1OS (Mg—Mn—Sr ferrite, magnetic filler) manufactured by Powdertech Co., Ltd.
*5: AW2-08PF-3F (amorphous alloy magnetic powder, magnetic filler) manufactured by Epson Atm ix Corporation
*6: AW2-08PF-3FG (amorphous alloy magnetic powder, magnetic filler) manufactured by Epson Atm ix Corporation
*7: gold-coated nickel powder (magnetic filler) manufactured by Oerlikon Metco
*8: Super 4S (heavy calcium carbonate) by Maruo Calcium Co., Ltd.
*9: SO-C6 (amorphous silica) manufactured by Admatechs K.K.
*10: 2MZ-A (imidazole type curing agent) manufactured by SHIKOKU CHEMICALS CORPORATION

### <Measurement of Viscosity of Curable Resin Composition>

The viscosity of each of the obtained thermosetting resin compositions was measured using a cone-flat plate type rotational viscometer (cone-plate type) (manufactured by Toki-Sangyo Co., Ltd., TV-30 type, rotor 3°×R9.7) under the measurement conditions of 30 second value at 25° C. and 5 rpm.

### <Measurement of Insulation Resistance>

Each of the curable resin compositions prepared as described above was coated on the entire surface of the FR-4 substrate on which the IPC-B-24 comb-shaped electrode (L/S=300 μm/300 μm) described in IPC-TM-650 was formed by screen printing so that the film thickness after curing was 20 to 40 μm, and the compositions were cured at 150° C. for 30 minutes in a hot air circulation drying furnace (DF610 manufactured by Yamato Scientific Co., Ltd.) to prepare evaluation substrates.

Next, with respect to each of the evaluation substrates, a 1 minute value, DC 100V, was measured at N=6 under an environmental atmosphere of a temperature of 20 to 25° C. and a relative humidity of 50 to 60% RH using an insulation resistance meter (R8340A ULTRA HIGH RESISTANCE METER, manufactured by ADVANTEST CORPORATION), and an average value thereof was used as an insulation resistance value. The measurement results are shown in Table 1 below.

### <Evaluation of Magnetic Property>

Magnetic property was evaluated in order to confirm properties such as noise suppression. Each of the curable resin compositions of Examples and Comparative Examples was coated on a copper foil with an applicator having a gap of 100 μm and heated at 150° C. for 30 minutes in a hot-air circulation drying furnace (DF610, manufactured by Yamato Scientific Co., Ltd.), and the curable resin compositions cured were cut out to a size of 1 cm×3 cm into evaluation substrates.

Next, using an E5071C ENA network analyzer manufactured by Keysight, the complex magnetic permeability (μ), the real part (μ′), the imaginary part (p′ and the imaginary number (j) of each of the evaluation substrates were measured at a temperature of 25° C. and 10 MHz to 1 GHz. The relationship between the respective items is expressed by p=p′-jp”, and the average value of 11 points around 100 MHz is used as an index. Note that, magnetic property was deemed to be present when p′>1.0. The evaluation results are shown in Table 1 below.

### <Evaluation of Hole Filling Property>

A multilayered printed wiring board having a through-hole formed to which a conductive part and an insulating part are formed on the inner wall was prepared by drilling from one side of a 3.2-thick multilayered printing wiring board (FR-4 material, model number MCL-E67, manufactured by Hitachi Chemical Company, Ltd. Co., Ltd.) which has a through hole and which is formed by providing a wiring layer made of copper plating (plated thickness: 25 μm) on the entire inner wall surface of a penetrating hole having an inner diameter of 0.3 mm and depth of 3.2 mm, up to the depth of 1.6 mm (drilling diameter 0.5 mm) to remove a part of the wiring layer so that the insulating layer is exposed.

The through holes of the multilayered printed wiring board were filled with the respective thermosetting resin compositions by a screen printing method, and in a state in which the substrate was laid against a rack so as to be at an angle of 90 degrees±10 degrees with respect to the mounting surface, the thermosetting resin composition was cured by heating at 150° C. for 30 minutes in a hot air circulation drying furnace (DF610 manufactured by Yamato Scientific Co., Ltd.).

Next, using the above-described substrate, the cross-section of the filled through holes were observed with an optical microscope and an electron microscope to check whether cracks have generated or not and whether delamination (peeling) had occured, and evaluation was made according to the following evaluation standards.

In the microscopic observation, the cross section of the through hole to be observed was formed as follows. That is, the multilayered printed wiring board including the through-holes was cut vertically in the thickness direction, and the cross-section of the through-holes was polished using SiC polishing paper (No. 500 and No. 2000, manufactured by Marumoto Struas K.K.) and a polishing machine (FORCIPOL-2V, manufactured by Herzog Japan Co., Ltd.).
∘: The total number of locations where cracks or delamination is generated is 0 or more and less than 2.
x: The total number of locations where cracks or delamination is generated is 2 or more.

The evaluation results are shown in Table 1 below.

### <Evaluation of Wiring Formation>

A multilayered printed wiring board having a through-hole formed to which a conductive part and an insulating part are formed on the inner wall was prepared by drilling from one side of a 3.2-thick multilayered printing wiring board (FR-4 material, model number MCL-E67, manufactured by Hitachi Chemical Company, Ltd. Co., Ltd.) which has a through hole and which is formed by providing a wiring layer made of copper plating (plated thickness: 25 μm) on the entire inner wall surface of a penetrating hole having an inner diameter of 0.3 mm and depth of 3.2 mm, up to the depth of 1.6 mm (drilling diameter 0.5 mm) to remove a part of the wiring layer so that the insulating layer is exposed.

The through holes of the multilayered printed wiring board as above were filled with the respective thermosetting resin compositions by a screen printing method, and in a state in which the substrate was laid against a rack so as to be at an angle of 90 degrees±10 degrees with respect to the mounting surface, the thermosetting resin composition was cured by heating at 150° C. for 30 minutes in a hot air circulation drying furnace (DF610 manufactured by Yamato Scientific Co., Ltd.). The evaluation substrates were produced by connecting the lead with solder on both sides of the substrates.

Next, each of the evaluation substrates was measured in a conduction mode using a digital multimeter (SK-6500, manufactured by Kaise Corporation) in an environmental atmosphere having a temperature of 20 to 25° C. and a humidity of 50 to 60% RH. The following evaluation criteria were used.
∘: No buzzer ringing, and circuit is formed as designed.
x: Buzzer ringing, and circuit is not formed as designed.

The evaluation results are shown in Table 1 below.

TABLE 1

| Composition | | EXAMPLES | | | COMPARATIVE EXAMPLES | | | |
|---|---|---|---|---|---|---|---|---|
| (weight by mass) | | 1 | 2 | 3 | 1 | 2 | 3 | 4 |
| Curable resin | jER828*¹ | 50 | 50 | 50 | 50 | 50 | 50 | 30 |
| | jER807*² | 50 | 50 | 50 | 50 | 50 | 50 | 20 |
| | jER1001*³ | — | — | — | — | — | — | 30 |
| Filler | E10S*⁴ | 460 | — | — | — | — | — | — |
| | AW2-08PF-3F*⁵ | — | 640 | — | — | — | — | 640 |
| | AW2-08PF-3FG*⁶ | — | — | 640 | — | — | — | — |
| | E-Fill 2758*⁷ | — | — | — | 810 | — | — | — |
| | Super 4S*⁸ | — | — | — | — | 200 | — | — |
| | SO-C6*⁹ | — | — | — | — | — | 200 | — |
| Curing agent | 2MZ-A*¹⁰ | 8 | 8 | 8 | 8 | 8 | 8 | 8 |

| | | | | | | | |
|---|---|---|---|---|---|---|---|
| Viscosity (dPa · s) | 920 | 2100 | 2900 | 500 | 450 | 450 | >3000 |
| Insulation resistance value (Ω) | 1.0 × 10⁵ | 7.0 × 10⁷ | 2.3 × 10¹² | <1.0 × 10¹ | 1.2 × 10¹³ | 1.2 × 10¹³ | 1.0 × 10⁵ |
| Magnetic property (μ′) | 5.3 | 5.9 | 5.9 | 4.5 | 1.0 | 1.0 | 5.3 |
| Hole filling property | ∘ | ∘ | ∘ | ∘ | ∘ | ∘ | x |
| Wiring formability | ∘ | ∘ | ∘ | x | ∘ | ∘ | ∘ |

As is apparent from the evaluation results in Table 1, it is understood that Examples 1 to 3, to which the curable resin composition satisfying the features of the present invention such as insulation resistance value etc. was applied, have excellent characteristics such as noise suppression due to the excellent magnetic property. In addition, it is also understood that Examples 1 to 3 have excellent hole-filling property and wiring formation property. On the contrary, it is found that Comparative Example 1, to which the curable resin composition failing to satisfy the specific insulation resistance value due to the use of a conductive magnetic filler was applied, has excellent characteristics such as noise suppression and hole filling; however, is found that the flexibility of the circuit forming was restricted by occurring the shorting-out when forming a circuit. In addition, Comparative Examples 2 and 3, to which a curable resin composition using only an inorganic filler that is not a magnetic filler was applied, have excellent hole-filling property and wiring formation property; however, are insufficient in properties such as noise suppression. Further, it is found that Comparative Example 4, to which a curable resin composition having a viscosity higher than 3000 dPa·s was applied, was excellent in properties such as noise suppression and wiring formation; however that the hole-filling property was poor in Comparative Example 4.

### DESCRIPTION OF REFERENCES

1,2 printed wiring board
3 Multilayered printed wiring board having a penetrating hole
4 Multilayered printed wiring board having a recess part
5a Penetrating hole in which inner wall surface is plated
5b Penetrating hole in which inner wall surface is not plated
6 Pre-cured product
7 Outer insulating layer
8 Copper foil
9 Substrate
10 Insulating layer
10a Insulating part
20a, 20b, 20c, 20d Wiring layer
30a, 30b, 30c, 30d Wiring layer
Penetrating hole
50a, 50b, 50c Wiring layer
20e, 30e, 50d Conductive part
60 Bottom part
70 Recess part

1. A curable resin composition, comprising:
a curable resin; and
a magnetic filler,
wherein the viscosity of the curable resin composition is in a range of 100 to 3000 dPa·s at 5.0 rpm as measured by a cone-flat plate type rotational viscometer in accordance with JIS-Z 8803:2011, and a cured product obtained by a process comprising curing the curable resin composition at 150° C. for 30 minutes has an insulation resistance value of 1.0×10⁵Ω or more.

2. The curable resin composition according to claim 1, wherein a content of the magnetic filler is in a range of 30 to 70 vol % based on a total amount of the curable resin composition.

3. The curable resin composition according to claim 1, wherein the magnetic filler comprises a magnetic material comprising magnetic particles and an insulating material covering surfaces of the magnetic particles.

4. A filling material for a penetrating hole or a recess part of a printed wiring board, comprising:
the curable resin composition of claim 1.

5. A cured product obtained by a process comprising curing the curable resin composition of claim 1.

6. A printed wiring board, comprising:
the cured product of claim 5.

7. The curable resin composition according to claim 2, wherein the magnetic filler comprises a magnetic material comprising magnetic particles and an insulating material covering surfaces of the magnetic particles.

8. A filling material for a penetrating hole or a recess part of a printed wiring board, comprising:
the curable resin composition of claim 2.

9. A cured product obtained by a process comprising curing the curable resin composition of claim 2.

10. A printed wiring board, comprising:
the cured product of claim 9.

11. A filling material for a penetrating hole or a recess part of a printed wiring board, comprising:
the curable resin composition of claim 3.

12. A cured product obtained by a process comprising curing the curable resin composition of claim 3.

13. A printed wiring board, comprising:
the cured product of claim 12.

14. A cured product obtained by a process comprising curing the filling material of claim 4.

15. A printed wiring board, comprising:
the cured product of claim 14.

16. A filling material for a penetrating hole or a recess part of a printed wiring board, comprising:
the curable resin composition of claim 7.

17. A cured product obtained by a process comprising curing the curable resin composition of claim 7.

18. A printed wiring board, comprising:
the cured product of claim 17.

19. A cured product obtained by a process comprising curing the filling material of claim 16.

20. A printed wiring board, comprising:
the cured product of claim 19.
